(19) United States
(12) Patent Application Publication
(10) Pub. No.: US 2024/0371777 A1
(43) Pub. Date: Nov. 7, 2024

(54) NITRIDE ETCH FOR CONSISTENT STEP HEIGHT FOR TSV REVEAL IN THE VIA MID FLOW

(71) Applicant: Intel Corporation, Santa Clara, CA (US)

(72) Inventors: Arijit KOLEY, Sherwood, OR (US); Ashish BHATIA, Portland, OR (US); Wayne M. LYTLE, Banks, OR (US); Stephen SUDIRGO, Beaverton, OR (US); Nora BERG, Buxton, OR (US); Patrick WHITING, Beaverton, OR (US); Michael MUSORRAFITI, Hillsboro, OR (US); Olawale Taiwo OLADEINDE, Hillsboro, OR (US); Emily TIMMINS, Beaverton, OR (US); Beatrice MURIUNGI, North Plains, OR (US); Matthew TAYLOR, Hillsboro, OR (US)

(21) Appl. No.: 18/141,887

(22) Filed: May 1, 2023

(51) Int. Cl. H01L 23/538; H01L 23/00; H01L 25/065

(52) U.S. Cl. CPC H01L 23/5384; H01L 24/08; H01L 24/16; H01L 25/0655; H01L 2224/08225; H01L 2224/16227

(57) ABSTRACT

Embodiments disclosed herein include an interposer. In an embodiment, the interposer comprises a substrate with a first surface and a second surface opposite from the first surface. In an embodiment, a via is provided through the substrate, where a portion of the via extends past the second surface. In an embodiment, a first layer is over the substrate, where the first layer is an electrically insulating material. In an embodiment, a second layer is over the first layer and over the portion of the via that extends past the second surface.

### TECHNICAL FIELD

Embodiments of the present disclosure relate to electronic systems, and more particularly to die-to-die interconnects with a uniform step height for through silicon via (TSV) reveal.

### BACKGROUND

In multi-die module architectures two or more compute dies may be communicatively coupled to each other through an interposer, such as a silicon interposer. In some instances power delivery through the interposer is provided by through silicon vias (TSVs) that pass through the interposer and couple with the overlying dies. In order to expose the TSV, a recessing or reveal process is needed. In some embodiments, a silicon etch exposes a top portion of the TSV. An insulating layer (e.g., a layer comprising silicon and nitrogen) is then deposited over the interposer. A polishing process is then used to expose the top surface of the TSV. The polishing process is difficult to implement in high volume manufacturing (HVM) environments due to substrate warpage and other non-uniformities.

Due to the manufacturing variability, the polishing process may over or under polish the insulating layer. In the case of over polishing, the step height difference between the top of the TSV and the top of the insulating layer is brought to zero, so that the two are substantially coplanar with each other. In such instances, it becomes difficult to determine alignment for subsequent manufacturing operations (e.g., bump formation). In the case of under polishing, the insulating layer remains over the top surface of the TSV, and an electrical connection cannot be made between the TSV and an overlying bump.

### BRIEF DESCRIPTION OF THE DRAWINGS

FIG. 1A is a cross-sectional illustration of a substrate with a through silicon via (TSV) that extends above the top of the substrate with an insulating layer over the TSV, in accordance with an embodiment.

FIG. 1B is a cross-sectional illustration of the substrate after a polishing process that removes too much of the TSV, in accordance with an embodiment.

FIG. 1C is a cross-sectional illustration of the substrate after a polishing process that does not remove enough of the insulating layer, in accordance with an embodiment.

FIG. 1D is a cross-sectional illustration of the substrate after a polishing process that removes enough of the insulating layer to expose the TSV while still maintaining a step height for alignment purposes, in accordance with an embodiment.

FIG. 2A is a plan view illustration of a substrate with a polishing process that does not expose the TSVs, or which exposes TSVs without a proper step height, in accordance with an embodiment.

FIG. 2B is a plan view illustration of a substrate with a polishing process that exposes the TSVs with a proper step height, in accordance with an embodiment.

FIGS. 3A-3D are cross-sectional illustrations depicting a process for forming a bump over a TSV, in accordance with an embodiment.

FIGS. 4A-4H are cross sectional illustrations depicting a process for forming a bump over a TSV with a controlled via reveal process, in accordance with an embodiment.

FIG. 5 is a cross-sectional illustration of an electronic system with an interposer with TSVs that are properly revealed so that they can be used for alignment while still allowing for electrical connection to an overlying bump, in accordance with an embodiment.

FIG. 6 is a schematic of a computing device built in accordance with an embodiment.

### EMBODIMENTS OF THE PRESENT DISCLOSURE

Described herein are electronic systems, and more particularly to die-to-die interconnects with a uniform step height for through silicon via (TSV) reveal, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, multi-die modules may include an interposer that is used to communicatively couple multiple dies together. The interposer may also include through silicon vias (TSVs) that enable power delivery and/or signal propagation through the thickness of the interposer. While referred to as TSVs, it is to be appreciated that the interposer may be materials other than silicon in some embodiments. In order to form bumps over the TSVs, a recessing or reveal operation is performed. After the reveal operation, an electrically insulating layer is provided over the top surface of the interposer and the exposed top end of the TSV. A polishing process is then used to expose the top surface of the TSV to enable electrical connection to a subsequently formed electrically conductive bump.

However, the polishing process is difficult to control, particularly when there is warpage or other deformation of the interposer substrate. Too much polishing removes the protrusion, and makes alignment for subsequent processes more difficult. Particularly, high volume manufacturing (HVM) solutions are not capable of providing the alignment, and manual intervention is needed. If the polishing fails to remove enough of the insulating layer, then the top surface of the TSV remains covered. This prevents the formation of an electrical connection between the overlying bump and the TSV.

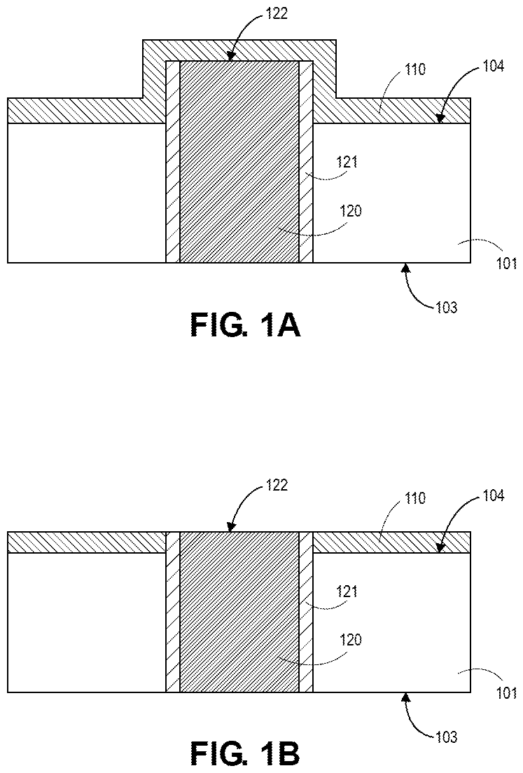

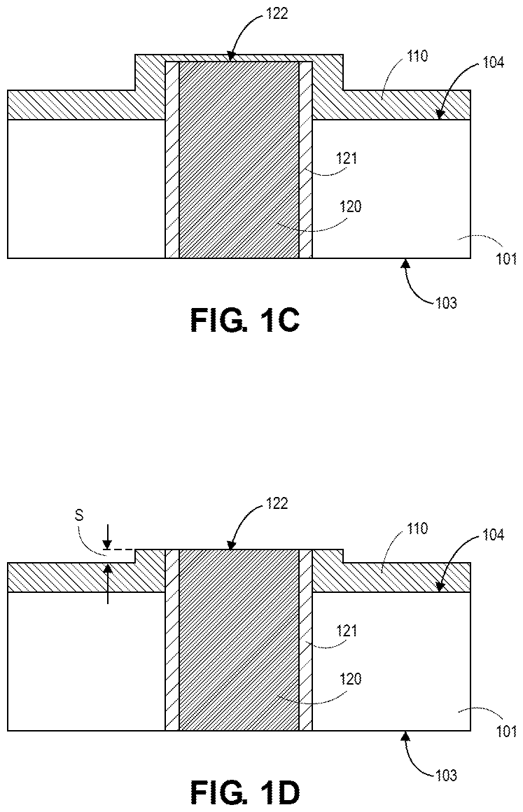

Referring now to FIG. 1A, a cross-sectional illustration of a substrate 101 is shown, in accordance with an embodiment. In an embodiment, the substrate 101 may be a silicon substrate or any other material suitable for use as an interposer. The substrate 101 may have a first surface 103 and a second surface 104 opposite from the first surface 103. A TSV 120 may be provided through a thickness of the substrate 101. The TSV 120 may be lined with a liner 121, such as an electrically insulating material comprising silicon and oxygen. In an embodiment, a top surface 122 of the TSV 120 may be provided above the second surface 104 of the substrate 101. That is, the second surface 104 may be referred to as being recessed below the top surface 122 of the TSV 120.

In an embodiment, an electrically insulating layer 110 may be provided over the second surface 104 and over the top end of the TSV 120. For example, the insulating layer 110 may be provided over a portion of the sidewalls of the TSV 120 (i.e., in contact with the liner 121) and over the top surface 122 of the TSV 120. The insulating layer 110 may comprise silicon and nitrogen (e.g., SiN_{X}).

Referring now to FIG. 1B, a cross-sectional illustration of the substrate 101 after a polishing process is shown, in accordance with an embodiment. In an embodiment, the polishing process in FIG. 1B may be considered as being over polished. That is, the step height between the top surface 122 of the TSV 120 and the top surface of the insulating layer 110 may be eliminated so that the top surface 122 of the TSV 120 is substantially coplanar with the top surface of the insulating layer 110. Such aggressive polishing may make it more difficult to provide alignment of a subsequent processing operations. For example, the formation of bumps over the top surface 122 may be rendered more difficult. In some embodiments, over polishing in such a manner may make it impossible to use HVM alignment tools. As such, subsequent layers need to be aligned using human intervention. This increases the cost of assembly and reduces the throughput.

Referring now to FIG. 1C, a cross-sectional illustration of the substrate 101 after a different polishing process is shown, in accordance with an embodiment. In an embodiment, the polishing process in FIG. 1C may be considered as being under polished. That is, the insulating layer 110 is not polished enough, and the top surface 122 of the TSV 120 remains covered. Since the top surface 122 is covered by an electrically insulating material, an electrical connection between the TSV 120 and an overlying bump cannot be made.

Referring now to FIG. 1D, a cross-sectional illustration of the substrate 101 after another polishing operation is shown, in accordance with an embodiment. The polishing done in FIG. 1D is the optimal outcome of the polishing operation. That is, enough of the insulating layer 110 is removed to expose the top surface 122 of the TSV 120, while still providing a step height S for the TSV 120. Accordingly, an electrical connection may be made, and alignment using HVM tools is possible.

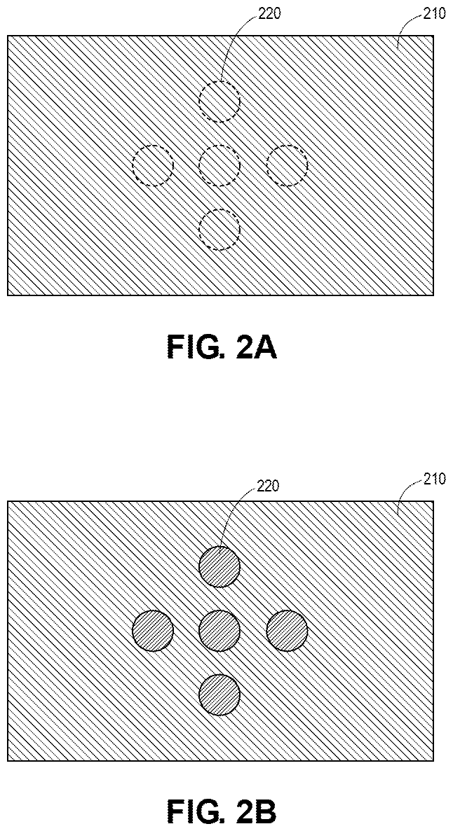

Referring now to FIGS. 2A and 2B, plan view illustrations of a device is shown under various polishing conditions. In FIG. 2A, the insulating layer 210 is not polished enough. As shown, the TSVs 220 that pass through the substrate remain covered by the insulating layer 210. As such, electrical coupling to overlying structures is not possible. In FIG. 2B, the insulating layer 210 is over polished. The over polishing exposes the TSVs 220, but removes any step height difference, which makes alignment difficult.

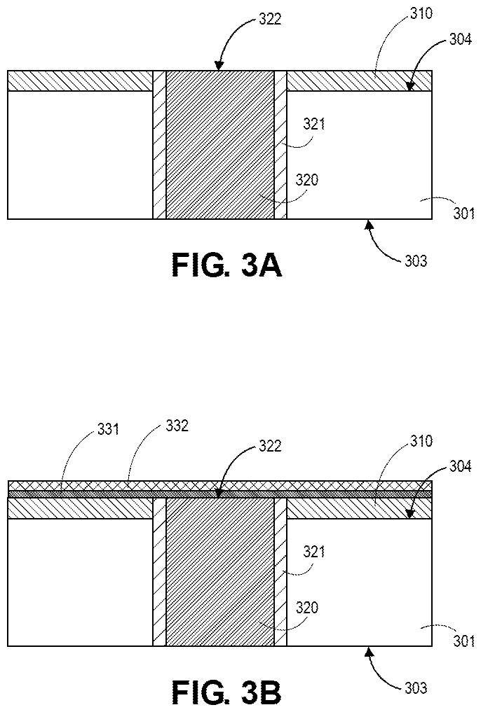

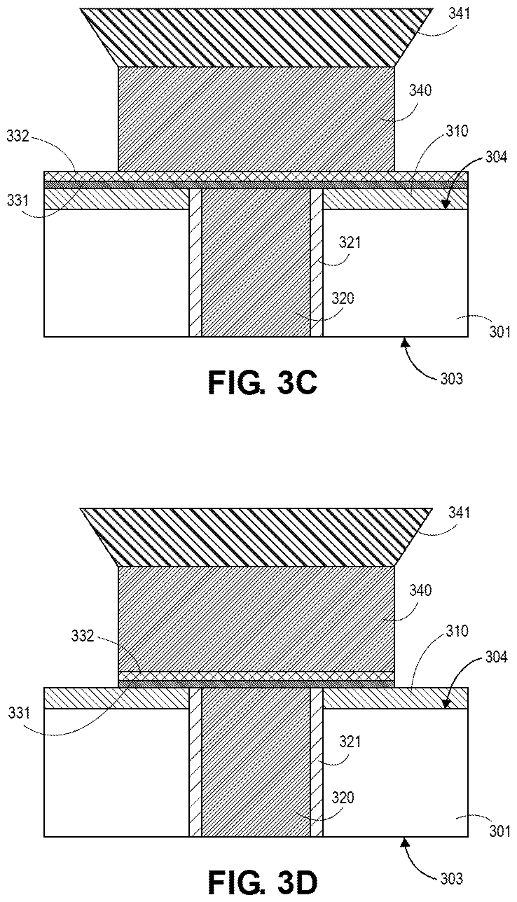

Referring now to FIGS. 3A-3D, a series of cross-sectional illustrations depicting a process for revealing a TSV 320 in an interposer substrate 301 is shown. The process shown in FIGS. 3A-3D provide an example of how over polishing can result in the need to manually align the overlying bumps instead of using automatic alignment processes.

Referring now to FIG. 3A, a cross-sectional illustration of a substrate 301 is shown, in accordance with an embodiment. The substrate 301 may be any suitable interposer material, such as one comprising silicon or the like. A TSV 320 may pass through a thickness between a first surface 303 and a second surface 304 of the substrate 301. The top surface 322 of the TSV 320 may be provided above the second surface 304 of the substrate 301. An insulating liner 321 may line the sidewalls of the TSV 320. For example, the insulating liner 321 may comprise silicon and oxygen in some instances. An insulating layer 310 may be provided over the second surface 304 of the substrate 301. The insulating layer 310 may comprise silicon and nitrogen or any other suitable insulating material. The top surface of the insulating layer 310 may be substantially coplanar with the top surface 322 of the TSV 320. That is, there is no discernable step height between the TSV 320 and the insulating layer 310.

Referring now to FIG. 3B, a cross-sectional illustration of the substrate 301 after a seed layer 332 is applied is shown, in accordance with an embodiment. In an embodiment, the seed layer 332 may comprise one or more of palladium, titanium, and copper. In an embodiment, the seed layer 332 may be provided over an electrically conductive barrier layer 331. For example, the barrier layer 331 may comprise titanium. As illustrated the seed layer 332 and the barrier layer 331 are applied with a blanket deposition process. Due to the lack of topography in the underlying structure, the seed layer 332 and the barrier layer 331 are substantially flat. Therefore, after the seed layer 332 is applied, it is not possible to visually discern the boundary between the TSV 320 and the insulating layer 310, and alignment is made more difficult.

Referring now to FIG. 3C, a cross-sectional illustration of the substrate 301 after a bump 340 is formed over the seed layer 332 is shown, in accordance with an embodiment. The bump 340 may be a copper bump 340 or the like. As shown, the bump 340 is ideally centered over the TSV 320. However, due to the overlying seed layer 332 and barrier 331, the bump 340 may not allow for automatic alignment of the bump 340. Instead, a manual alignment process is needed, which significantly slows down the processing. After deposition of the bump 340 a solder 341 or the like may be disposed over the bump 340.

Referring now to FIG. 3D, a cross-sectional illustration of the substrate 301 after the residual seed layer 332 and barrier 331 are removed is shown, in accordance with an embodiment. The seed layer 332 and the barrier 331 may be removed with an etching process, such as a flash etching process, or the like. As such, portions of the insulating layer 310 are exposed again.

As can be appreciated, the polishing process used to produce the starting structure for FIG. 3A is made difficult since both under polishing and over polishing can result in manufacturing defects. This means that a purposely aggressive polish and a purposely shallow polish can both result in defective devices. The polishing process is further complicated due to warpage or other deformation of the substrate 101. Due to warpage, a given polishing process may result in both under polishing and over polishing within the same substrate.

Accordingly, embodiments disclosed herein include a process flow that omits the polishing in favor of an etching process. In such embodiments, the insulating layer can be removed in a uniform manner across the entire surface of the substrate. A uniform step height with a complete reveal of the top surface of the TSV is possible. The preservation of the step height allows for accurate alignment even after the seed layer is deposited. This is because the seed layer conforms to the topography, and the step height persists. In an embodiment, the step height across all TSVs is maintained uniform. This allows for easier HVM alignment processes, which decreases costs and improves throughput. Further, electrical coupling between the TSV and an overlying bump is provided.

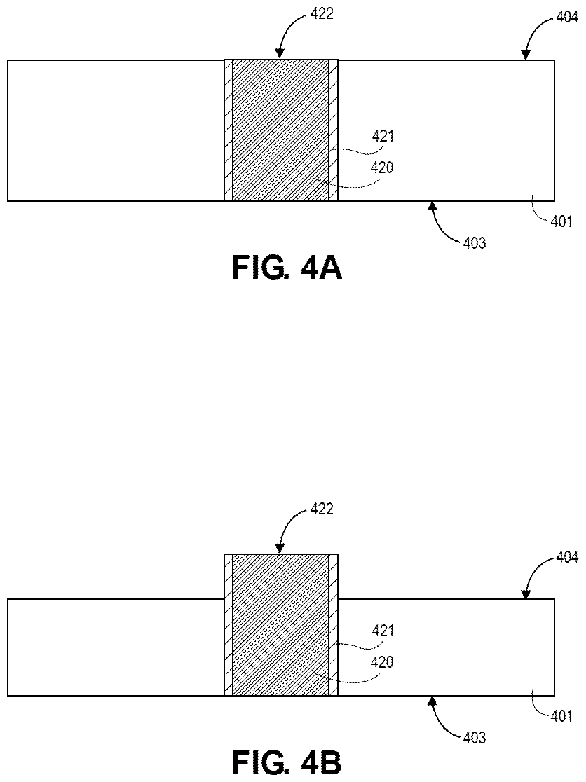

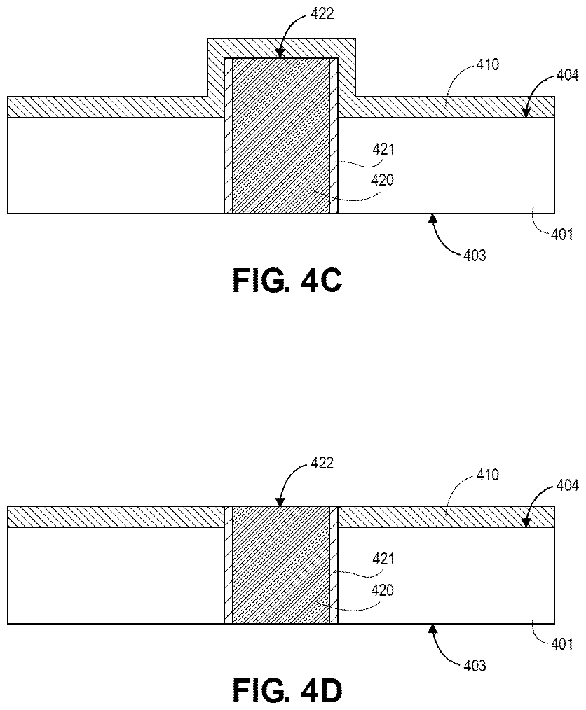

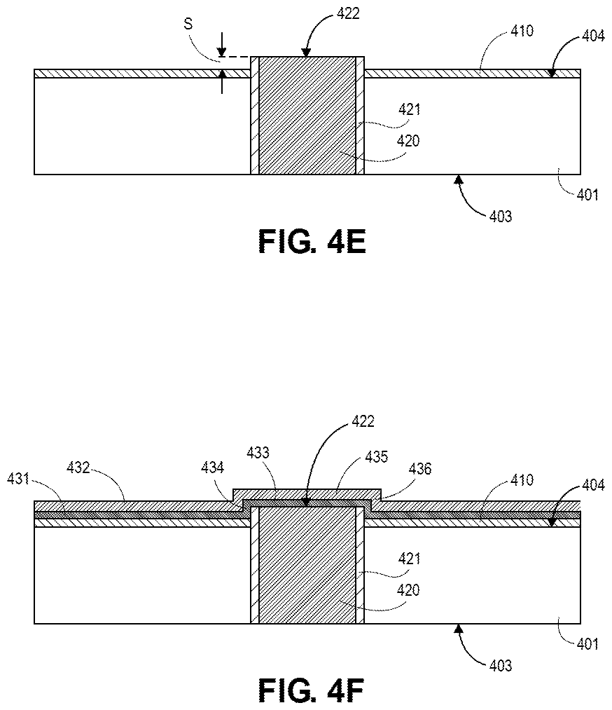

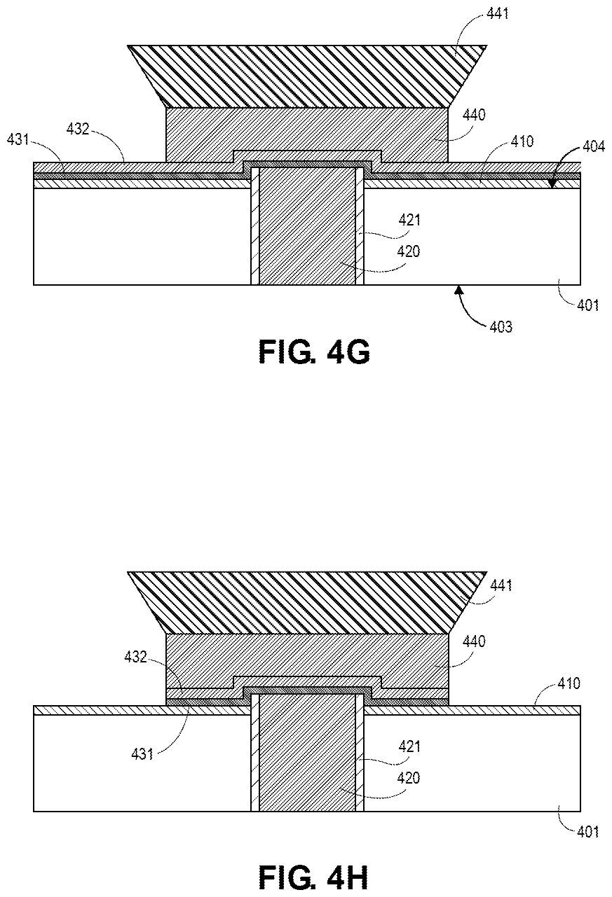

Referring now to FIGS. 4A-4H, a series of cross-sectional illustrations depicting a process for forming an interposer with bumps that are properly aligned with the underlying TSVs is shown, in accordance with an embodiment. Generally, the process flow described in FIGS. 4A-4H leverages an etching process to maintain the step height topography needed for accurate alignment of the bump to the TSV. While a single TSV is shown in FIGS. 4A-4H, it is to be appreciated that multiple TSVs may be processed in parallel. The parallel processing yields a uniform step height due to the use of an etching process in the place of a polishing process.

Referring now to FIG. 4A, a cross-sectional illustration of a substrate 401 is shown, in accordance with an embodiment. In an embodiment, the substrate 401 may be a material suitable for use as an interposer in a multi-die module. For example, the substrate 401 may comprise silicon, glass, or the like. The substrate 401 may have any suitable thickness. For example, the substrate 401 may include a thickness between 100 μm and 5,000 μm. Though, thinner or thicker substrates 401 may also be used in some embodiments.

In an embodiment, TSVs 420 may be provided through a thickness of the substrate 401 between a first surface 403 and a second surface 404 of the substrate 401. The TSV 420 may comprise copper or any other electrically conductive material or materials. While referred to as a “TSV” 420, it is to be appreciated that the substrate 401 does not necessarily always include silicon, as is described above. In an embodiment, a liner 421 may be provided over sidewalls of the TSV 420. The liner 421 may comprise an electrically insulating material. For example, the liner 421 may comprise silicon and oxygen in some embodiments. In the illustrated embodiment, the TSV 420 has substantially vertical sidewalls. Though, in other embodiments, sidewalls of the TSV 420 may be non-vertical or tapered. As shown in FIG. 4A, a top surface 422 of the TSV 420 is substantially coplanar with the second surface 404 of the substrate 401. That is, at this point in the process flow, there may not be any discernable topography on the top surface of the substrate 401.

Referring now to FIG. 4B, a cross-sectional illustration of the substrate 401 after a recessing process is shown, in accordance with an embodiment. In an embodiment, the recessing process may result in the second surface 404 being recessed below the top surface 422 of the TSV 420. In an embodiment, the recessing process may be implemented with an etching process. For example, a wet etching process or a dry etching process may be used to recess the second surface 404 below the top surface 422 of the TSV 420. In an embodiment, the top surface 422 of the TSV 420 may be approximately 1 μm or more above the second surface 404. For example, the recessing process may include the removal of up to approximately 3 μm or more of silicon. For example, the removal of silicon may be between approximately 2.5 μm and approximately 10 μm. As a result of the recessing, a topography is provided on the second surface 404 of the substrate 401. As used herein, “approximately” may refer to a range of values that are within ten percent of the stated value. For example, approximately 3 μm may refer to a range between 2.7 μm and 3.3 μm.

Referring now to FIG. 4C, a cross-sectional illustration of the substrate 401 after an insulating layer 410 is deposited over the exposed surfaces is shown, in accordance with an embodiment. The insulating layer 410 may be any suitable electrically insulating material. For example, the insulating layer 410 may comprise silicon and nitrogen. In some embodiments, the insulating layer 410 is a material that is etch selective to the liner 421. The insulating layer 410 may be deposited with a blanket deposition process. That is, a uniform insulating layer 410 is provided across a surface of the substrate 401. Additionally, the insulating layer 410 may be a conformal layer. That is, the insulating layer 410 may conform to the topography provided by the recessing operation described in FIG. 4B. For example, portions of the insulating layer 410 may be provided over the second surface 404, over the top surface 422 of the TSV 420, and along the portions of the sidewall of the TSV 420 above the second surface 404. However, the liner 421 may keep the insulating layer 410 from directly contacting a sidewall of the TSV 420.

Due to the conformal nature of the insulating layer 410, a step profile is still maintained. In some embodiments, the thickness of the insulating layer 410 may be less than a standoff height provided between the top surface 422 of the TSV 420 and the second surface 404 of the substrate 401. For the portion of the insulating layer 410 overlying the second surface 404, the top surface of the insulating layer 410 may be between the second surface 404 and the top surface 422 of the TSV 420. Though, embodiments are not limited to such configurations, and the top surface of the insulating layer 410 may be above the top surface 422 of the TSV 420. In an embodiment, the insulating layer 410 may have a thickness that is up to approximately 2.0 μm or even larger.

Referring now to FIG. 4D, a cross-sectional illustration of the substrate 401 after a polishing process is shown, in accordance with an embodiment. In an embodiment, the polishing process may be an aggressive polish so that the top surface 422 of the TSV 420 is exposed. That is, even when accounting for warpage, substantially all of the TSVs 420 on a substrate 401 will be exposed by the polishing process. The polishing process may remove the topography provided in previous steps. That is, the top surface 422 of the TSV 420 may be substantially coplanar with the top surface of the insulating layer 410. However, as will be described in greater detail below, a topographical feature will be reintroduced in a self-aligned process. In an embodiment, the polishing process may include any suitable polishing process. For example, a chemical mechanical polishing (CMP) process may be used in some embodiments. The polishing process may result in the thickness of the insulating layer 410 being reduced. For example, the thickness of the insulating layer 410 may be approximately 2 μm or less, or approximately 1 μm or less.

Referring now to FIG. 4E, a cross-sectional illustration of the substrate 401 after the insulating layer 410 is recessed is shown, in accordance with an embodiment. In an embodiment, the insulating layer 410 may be recessed with an etching process. For example, a timed wet etching process can be used in some embodiment. In other embodiments, a dry etching process may be used to recess the insulating layer 410. In an embodiment, the etching process is a self-aligned etch. Due to the etch selectivity between the insulating layer 410 and the TSV 420 (and liner 421), the edge of the TSV 420 will be reintroduced as a structural feature at the top surface of the substrate 401 without the need of a patterning mask. For example, a step height S will be reintroduced between the top of the insulating layer 410 and the top surface 422 of the TSV 420. In an embodiment, the step height S may be approximately 0.1 μm or greater. The residual portion of the insulating layer 410 may have a thickness that is approximately 1 μm or greater. For example, the thickness of the insulating layer 410 may be approximately 5 μm or greater.

Referring now to FIG. 4F, a cross-sectional illustration of the substrate 401 after a seed layer 432 is deposited is shown, in accordance with an embodiment. In an embodiment, the seed layer 432 may comprise one or more of palladium, titanium, and copper. In some embodiments, the structure may also include a barrier layer 431 below the seed layer 432. The barrier layer 431 may include any suitable electrically conductive diffusion limiting material. For example, the barrier layer 431 may comprise titanium in some embodiments. In some instances, the seed layer 432 and the barrier layer 431 may be considered a single layer, depending on the composition of each layer 431 and 432. For example, a single material composition may function as both a barrier material and a seed material. The seed layer 432 and the barrier layer 431 may have a thickness that is approximately 500 nm or less, or approximately 100 nm or less.

As shown in FIG. 4F, the seed layer 432 and the barrier layer 431 are conformally deposited. Due to the conformal nature of the two layers, the topography provided in the previous operation is maintained after the deposition process shown in FIG. 4F. For example, the barrier layer 431 may have vertical portions 434 along sidewalls of the TSV 420 and a horizontal portion 433 over the top surface 422 of the TSV 420. Similarly, the seed layer 432 may have vertical portions 436 that are connected to each other by a horizontal portion 435 that is over the top surface 422 of the TSV 420.

The topography that persists into the structure shown in FIG. 4F enables alignment of a bump in a subsequent processing operation, despite the presence of a single blanket seed layer 432. That is, the location of the step height difference in the seed layer at the vertical portions 436 can be used as an indication for where the underlying TSV 420 is located, even though the top surface 422 of the TSV 420 cannot be seen after depositing the seed layer 432.

Referring now to FIG. 4G, a cross-sectional illustration of the substrate 401 after a bump 440 is disposed over the TSV 420 is shown, in accordance with an embodiment. As described above, the topography of the seed layer 432 can be used as a guide to align the patterning features used to deposit the bump 440. For example, a dry film resist can be deposited and patterned. The bump 440 can then be selectively plated up from the seed layer 432 using a plating process, such as an electrolytic plating process. After the bump 440 is plated, the dry film resist can be removed. In an embodiment, the bump 440 may have a width that is wider than a width of the TSV 420.

In an embodiment, the bump 440 is an electrically conductive material, such as copper or the like. In some instances, the bump 440 is the same material as the seed layer 432. In such instances, it may be difficult to distinguish the seed layer 432 from the bump 440. In such instances, the barrier layer 431 may still be present and provide a distinguishing feature that indicates a process in accordance with embodiments described herein was used. More generally, either one or both of the barrier layer 431 and the seed layer 432 may include a U-shaped structure that wraps around a top end of the TSV 420. In the embodiment shown in FIG. 4G, the U-shape is upside down and consists of vertical portions that are connected at their top ends by a horizontal portion that is provided over the top surface 422 of the TSV 420.

In an embodiment, the processing may continue with the formation of a solder bump 441 over the bump 440. The solder bump 441 may be used as a solder to join with a die (not shown) after the processing of the substrate 401 is completed. The solder bump 441 may be plated or otherwise dispensed. While a solder bump 441 is shown in FIG. 4G, it is to be appreciated that embodiments may optionally omit the solder bump 441. For example, the subsequent connection to the die may be a solderless connection, or the solder bump 441 may be provided on only the die side of the connection. That is, a bumpless die-to-die interconnect architecture may be used to couple the substrate 401 to the overlying die (not shown).

Referring now to FIG. 4H, a cross-sectional illustration of the substrate 401 after the residual seed layer 432 and barrier layer 431 are removed is shown, in accordance with an embodiment. The residual seed layer 432 and barrier layer 431 outside of the bump 440 may be removed with an etching process. For example, a timed wet etch (e.g., a flash etch) may be used in order to remove the residual seed layer 432 and the barrier layer 431. That is, a width of the seed layer 432 and barrier layer 431 may be substantially the same width as the bump 440. After removal of the two layers, portions of the insulating layer 410 may be exposed again. The substrate 401 may then be ready for coupling with one or more additional dies in a die-to-die bonding configuration.

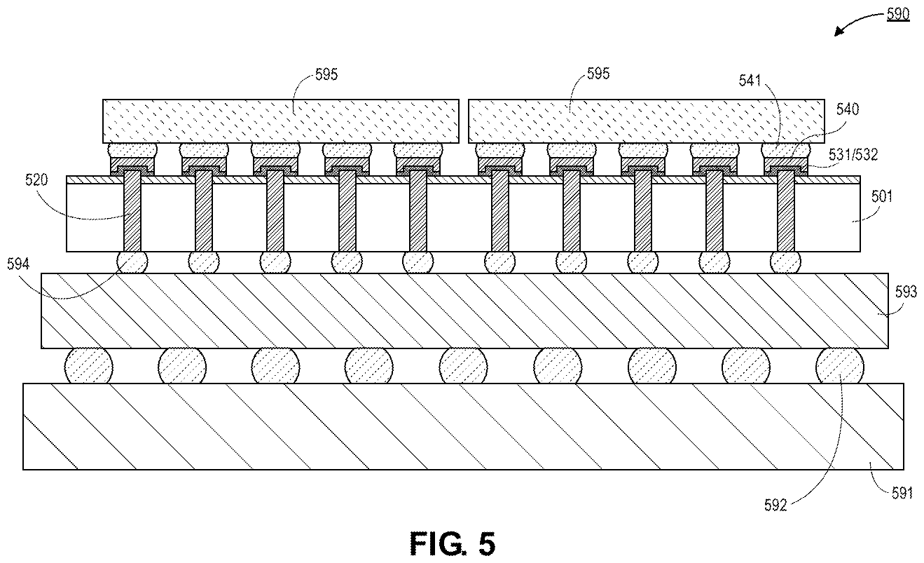

Referring now to FIG. 5, a cross-sectional illustration of an electronic system 590 is shown, in accordance with an embodiment. The electronic system 590 may comprise a board 591, such as a printed circuit board (PCB). The board 591 may be coupled to a package substrate 593 by interconnects 592. The interconnects 592 may comprise solder balls, sockets, or any other suitable interconnect architecture. In an embodiment, the package substrate 593 may be coupled to a multi-die module by interconnects 594, such as solder balls or the like.

In an embodiment, the multi-die module comprises an interposer 501 and two or more dies 595. The two or more dies 595 may be communicatively coupled together through the interposer 501. For example, the interposer 501 may include a semiconductor substrate such as silicon. The interposer 501 may also include TSVs 520 (e.g., for power delivery to the top dies 595). The TSVs 520 may have a protruding end (i.e., the top end in FIG. 5) that is surrounded by a U-shaped seed layer/barrier layer 531/532. A bump 540 may then be provided over the layers 531/532. In an embodiment, the topography of the TSVs 520 allows for proper alignment of the bumps 540. In an embodiment, an interconnect 541 may be provided between the bumps 540 and the overlying dies 595. While shown as a solder interconnect 541, it is to be appreciated that any first level interconnect (FLI) architecture may be used to bond the dies 595 to the bumps 540.

In an embodiment, the dies 595 may be any type of die. For example, the dies 595 may include one or more of a central processing unit (CPU), a graphics processing unit (GPU), an XPU, a system on a chip (SoC), a communications die, and a memory.

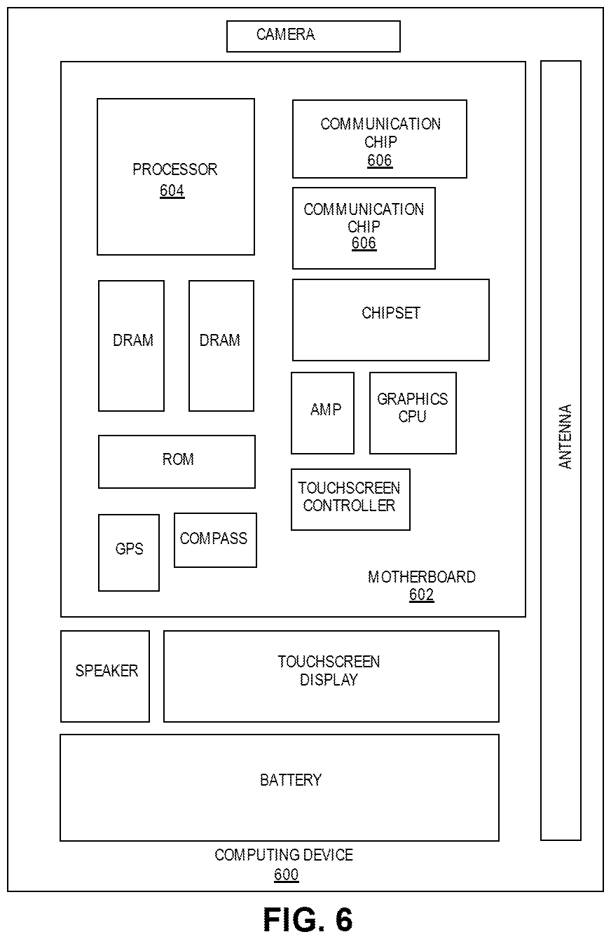

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor may be part of an electronic system with an interposer that is coupled to one or more dies through a TSV with a protruding end, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip may be part of an electronic system with an interposer that is coupled to one or more dies through a TSV with a protruding end, in accordance with embodiments described herein.

In an embodiment, the computing device 600 may be part of any apparatus. For example, the computing device may be part of a personal computer, a server, a mobile device, a tablet, an automobile, or the like. That is, the computing device 600 is not limited to being used for any particular type of system, and the computing device 600 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an interposer, comprising: a substrate with a first surface and a second surface opposite from the first surface; a via through the substrate, wherein a portion of the via extends past the second surface; a first layer over the substrate, wherein the first layer is an electrically insulating material; and a second layer over the first layer and over the portion of the via that extends past the second surface.

Example 2: the interposer of Example 1, wherein a step height of the portion of the via that extends past the second surface is approximately 0.1 μm or greater.

Example 3: the interposer of Example 1 or Example 2, wherein the second layer comprises: a third layer comprising titanium; and a fourth layer comprising copper.

Example 4: the interposer of Example 3, wherein the fourth layer comprises a barrier layer, and wherein the fourth layer comprises a seed layer.

Example 5: the interposer of Examples 1-4, wherein the first layer comprises silicon and nitrogen.

Example 6: the interposer of Examples 1-5, wherein the substrate comprises silicon.

Example 7: the interposer of Examples 1-6, wherein a liner surrounds the via.

Example 8: the interposer of Examples 1-7, further comprising: an electrically conductive bump over the second layer.

Example 9: the interposer of Example 8, wherein a width of the electrically conductive bump is substantially equal to a width of the second layer.

Example 10: the interposer of Example 9, wherein the first layer is wider than the second layer.

Example 11: the interposer of Examples 1-10, wherein the via is a through silicon via (TSV) that passes through an entire thickness of the substrate.

Example 12: a multi-die module, comprising: an interposer, comprising: a substrate with a first surface and a second surface opposite from the first surface; a via through the substrate, wherein an end of the via extends up past the second surface of the substrate; and a layer comprising copper around the end of the via; a first die coupled to the interposer; and a second die coupled to the interposer.

Example 13: the multi-die module of Example 12, wherein the first die is communicatively coupled to the second die through the interposer.

Example 14: the multi-die module of Example 12 or Example 13, wherein the first die is coupled to the interposer through a bump or through a bumpless die-to-die interconnect.

Example 15: the multi-die module of Examples 12-14, wherein the layer comprising copper is over a layer comprising titanium.

Example 16: the multi-die module of Examples 12-15, wherein the layer comprising copper has a horizontal portion over a top of the via, and vertical portions along sidewalls of the via.

Example 17: the multi-die module of Examples 12-16, wherein a layer comprising silicon and nitrogen is provided over the second surface of the substrate.

Example 18: an electronic system, comprising: a board; a package substrate coupled to the board; and a multi-die module coupled to the package substrate, wherein the multi-die module comprises: an interposer with a via with an end that extends past a top surface of the interposer; a layer comprising copper over and around the end of the via; a first die coupled to the interposer through the bump; and a second die coupled to the interposer.

Example 19: the electronic system of Example 18, wherein the via has a step height above the top surface of the interposer that is approximately 0.1 μm or greater.

Example 20: the electronic system of Example 18 or Example 19, wherein the electronic system is part of a personal computer, a server, a mobile device, a tablet, or an automobile.

What is claimed is:

1. An interposer, comprising:
a substrate with a first surface and a second surface opposite from the first surface;
a via through the substrate, wherein a portion of the via extends past the second surface;
a first layer over the substrate, wherein the first layer is an electrically insulating material; and
a second layer over the first layer and over the portion of the via that extends past the second surface.

2. The interposer of claim 1, wherein a step height of the portion of the via that extends past the second surface is approximately 0.1 μm or greater.

3. The interposer of claim 1, wherein the second layer comprises:
a third layer comprising titanium; and
a fourth layer comprising copper.

4. The interposer of claim 3, wherein the third layer comprises a barrier layer, and wherein the fourth layer comprises a seed layer.

5. The interposer of claim 1, wherein the first layer comprises silicon and nitrogen.

6. The interposer of claim 1, wherein the substrate comprises silicon.

7. The interposer of claim 1, wherein a liner surrounds the via.

8. The interposer of claim 1, further comprising:
an electrically conductive bump over the second layer.

9. The interposer of claim 8, wherein a width of the electrically conductive bump is substantially equal to a width of the second layer.

10. The interposer of claim 9, wherein the first layer is wider than the second layer.

11. The interposer of claim 1, wherein the via is a through silicon via (TSV) that passes through an entire thickness of the substrate.

12. A multi-die module, comprising:
an interposer, comprising:
a substrate with a first surface and a second surface opposite from the first surface;
a via through the substrate, wherein an end of the via extends up past the second surface of the substrate; and
a layer comprising copper around the end of the via;
a first die coupled to the interposer; and
a second die coupled to the interposer.

13. The multi-die module of claim 12, wherein the first die is communicatively coupled to the second die through the interposer.

14. The multi-die module of claim 12, wherein the first die is coupled to the interposer through a bump or through a bumpless die-to-die interconnect.

15. The multi-die module of claim 12, wherein the layer comprising copper is over a layer comprising titanium.

16. The multi-die module of claim 12, wherein the layer comprising copper has a horizontal portion over a top of the via, and vertical portions along sidewalls of the via.

17. The multi-die module of claim 12, wherein a layer comprising silicon and nitrogen is provided over the second surface of the substrate.

18. An electronic system, comprising:
a board;
a package substrate coupled to the board; and
a multi-die module coupled to the package substrate, wherein the multi-die module comprises:
an interposer with a via with an end that extends past a top surface of the interposer;
a layer comprising copper over and around the end of the via;
a first die coupled to the interposer through the bump; and
a second die coupled to the interposer.

19. The electronic system of claim 18, wherein the via has a step height above the top surface of the interposer that is approximately 0.1 μm or greater.

20. The electronic system of claim 18, wherein the electronic system is part of a personal computer, a server, a mobile device, a tablet, or an automobile.
